(19) United States
(12) Patent Application Publication
(10) Pub. No.: US 2012/0190176 A1
(43) Pub. Date: Jul. 26, 2012

(54) CATALYTIC CVD EQUIPMENT, METHOD FOR FORMATION OF FILM, AND PROCESS FOR PRODUCTION OF SOLAR CELL

(75) Inventors: Motohide KAI, Takaishi-shi (JP); Shuji OSONO, Sammu-shi (JP); Satohiro OKAYAMA, Chigasaki-shi (JP); Hideyuki OGATA, Chigasaki-shi (JP)

(73) Assignees: ULVAC, INC., Chigasaki-shi (JP); SANYO ELECTRIC CO., LTD., Moriguchi-shi (JP)

(21) Appl. No.: 13/436,202

(22) Filed: Mar. 30, 2012

Related U.S. Application Data
(63) Continuation of application No. PCT/JP2010/067286, filed on Oct. 1, 2010.

(30) Foreign Application Priority Data
Oct. 2, 2009 (JP) 2009-230598

(51) Int. Cl. H01L 21/20; C23C 16/52

(52) U.S. Cl. 438/478; 118/724; 257/E21.09

(57) ABSTRACT

In a catalytic CVD equipment, the control unit controls a temperature of the catalytic wires to a standby temperature at predetermined time intervals before and after the film is formed. The standby time is a predetermined temperature which is lower than the temperature of the catalytic wires when the film is formed, and is higher than room temperature.

### CROSS REFERENCE

This application is a Continuation of PCT Application No. PCT/JP2010/067286 filed on Oct. 1, 2010, and claims the priority of Japanese Patent Application No. 2009-230598 filed on Oct. 2, 2009, the content of both of which is incorporated herein by reference.

### TECHNICAL FIELD

The present invention relates to a catalytic CVD equipment for performing formation of film on a film-formed substrate, a method for formation of film, and a process for production of solar cell.

### BACKGROUND ART

As a method for forming a predetermined deposited film on a substrate at the time of manufacturing a variety of semiconductor devices such as solar cells, in general, a CVD technique (a Chemical Vapor Deposition technique) is conventionally known. As one kind of such CVD technique, in recent years, a catalytic CVD technique utilizing Catalytic Chemical Vapor Deposition has been discussed (Patent Document 1, for example).

In the catalytic CVD technique, a raw material gas to be supplied into a reaction chamber is decomposed by employing a catalytic wire that is made of heated tungsten, molybdenum or the like and then a deposited film is formed on a substrate that is held on a holder. The catalytic CVD technique is expected as a method for formation of film, by which a substrate surface or a deposited film surface is less adversely affected, since such plasma discharge in a plasma CVD technique is not utilized.

### PRIOR ART DOCUMENT(S)

### Patent Document

Patent Document 1: Japanese Unexamined Patent Application Publication No. 2005-327995

### SUMMARY OF THE INVENTION

However, in the conventional catalytic CVD equipment, a catalytic wire easily breaks, there is a need to frequently replace such a faulty catalytic wire with its replacement wire; and therefore, there has been a problem that manufacturability is degraded.

Accordingly, the present invention has been made to solve the above-described problem, and it is an object of the present invention to provide a catalytic CVD equipment, a method for formation of film, and a process for production of solar cell which are capable of realizing extended serviceable life of a catalytic wire.

A catalytic CVD equipment according to a feature of the present invention is summarized as a catalytic CVD equipment for performing formation of film by supplying a raw material gas to a catalytic wire that is installed and heated in a reaction chamber and then depositing generated decomposed species on a film-formed substrate in the reaction chamber, the device comprising a control unit that is capable of controlling a temperature of the catalytic wire so as to reach a decomposition temperature of the raw material gas, at a time of formation of film onto the film-formed substrate, the control unit being capable of controlling the temperature of the catalytic wire so as to be a predetermined temperature which is lower than the temperature of the catalytic wire when the film is formed, and is higher than room temperature, at each of predetermined time intervals before and after the film is formed.

The catalytic CVD equipment according to the feature of the present invention is capable of maintaining a temperature of a catalytic wire at a predetermined temperature which is lower than a temperature when the film is formed, and is higher than room temperature at each of predetermined time intervals before and after the film is formed. Therefore, according to the present invention, shrinkage and expansion of the catalytic wire can be mitigated, thus making it possible to realize extended serviceable life of the catalytic wire.

In addition, a catalytic CVD equipment according to a feature of the present invention is summarized a catalytic CVD equipment for performing formation of film by supplying a raw material gas to a catalytic wire that is installed and heated in a reaction chamber and then depositing generated decomposed species on a film-formed substrate in the reaction chamber, the device comprising a power source for supplying power to the catalytic wire, the device comprising a control unit controlling power supply to the catalytic wire so that the temperature of the catalytic wire is set at a decomposition temperature of the raw material gas at the time of formation of film onto the film-formed substrate, the control unit controlling power supply to the catalytic wire so that the temperature of the catalytic wire is set at a predetermined temperature which is lower than the temperature of the catalytic wire when the film is formed, and is higher than room temperature at each of the predetermined time intervals before and after the film is formed.

According to such a catalytic CVD equipment, power is continuously supplied to a catalytic wire at the time of normal operation, and it is possible to exercise control so as to disable switching of start and stop of power supply; and therefore, shrinkage and expansion that occur with the catalytic wire due to repetition of switching of start and stop of power supply can be mitigated. As a result, extended serviceable life of the catalytic wire can be realized.

In the catalytic CVD equipment according to the features of the present invention, the catalytic wire may be temperature-controlled by means of continuous power supply at each of the predetermined time intervals before and after the film is formed.

In the catalytic CVD equipment according to the features of the present invention, a temperature of the catalytic wire may be controlled to reach a temperature which is lower than the decomposition temperature at each of the predetermined time intervals before and after the film is formed.

In the catalytic CVD equipment according to the features of the present invention, a predetermined temperature may be a temperature which is higher than a temperature at which an ductile-brittle transition occurs with at least part of a catalytic wire. In this case, a repetitive occurrence of the ductile-brittle transition with the catalytic wire can be prevented, thus making it possible to realize extended serviceable life of the catalytic wire.

In the catalytic CVD equipment according to the features of the present invention, a predetermined temperature may be a temperature at which, in a case where the predetermined film has been formed on the film-formed substrate, a temperature of a film-formed substrate can be maintained to be lower than a temperature at which film quality of a predetermined film varies. In this case, film quality of a film such as an amorphous semiconductor film or a finely crystalline semiconductor film that is formed on the film-formed substrate can be restrained from varying at a time other than when the film is formed.

A method for formation of film according to an aspect of the present invention is summarized as including the step of forming a film on a film-formed substrate by employing the catalytic CVD equipment according to any one of the foregoing present invention.

A process for production of solar cell according to an aspect of the present invention is summarized as including the step of forming a film on a film-formed substrate by employing the catalytic CVD equipment according to any one of the foregoing present invention.

According to the present invention, a catalytic CVD equipment which is capable of realizing extended serviceable life of a catalytic wire can be provided. In addition, a method for formation of film and a process for production of solar cell with their improved manufacturability by employing the catalytic CVD equipment can be provided.

### BRIEF DESCRIPTION OF THE DRAWINGS

FIG. 1 is a schematic diagram showing a configuration of a catalytic CVD equipment 100 according to an embodiment.

FIG. 2 is a view for explaining flow of formation of firm according to Example.

### BEST MODE FOR CARRYING OUT THE INVENTION

Hereinafter, a catalytic CVD equipment according to an embodiment of the present invention will be described with reference to the drawings. It is to be noted that, in the following description of drawings, the same or similar constituent elements are designated by the same or similar reference numerals.

However, it should be kept in mind that the drawings are schematic, and a rate of each dimension is different from actual one. Therefore, specific dimensions or the like should be determined in consideration of the following description. In addition, it is a matter of course that portions with their different dimensional interrelationships or rates are included in the drawings.

[Relationship Between Power Supply to Catalytic Wire and Serviceable Life of Catalytic Wire]

In the conventional catalytic CVD equipment, a catalytic wire easily breaks, there is a need to frequently replace such a faulty catalytic wire with its replacement wire; and therefore, there has been a problem that manufacturability is degraded.

Accordingly, the present inventors made their utmost efforts in study with respect to why the catalytic wire easily breaks. As a result, it was determined that there had been a problem in that power supply to the catalytic wire is stopped after the completion of formation of film and then power supply to the catalytic wire is started again at the time of start of formation of film.

Specifically, when power supply to the catalytic wire has been stopped after the completion of formation of film, a temperature of the catalytic wire lowers from a temperature when the film is formed (for example, 1,600 degrees Centigrade to 2,000 degrees Centigrade) to the order of room temperature within several seconds due to a small thermal capacity of the catalytic wire; and therefore, the catalytic wire rapidly shrinks. In addition, when power supply to the catalytic wire has been started, the temperature of the catalytic wire rises from the order of room temperature to the temperature when the film is formed within several seconds; and therefore, the catalytic wire rapidly expands. It was determined that such shrinkage and expansion are repeated every time stop and start of power supply is switched, thereby reducing serviceable life of the catalytic wire.

The present invention contrives control of power supply to a catalytic wire to thereby realize extended serviceable life of the catalytic wire. Hereinafter, a description will be furnished, focusing on control of power supply to the catalytic wire.

[Configuration of Catalytic CVD Equipment]

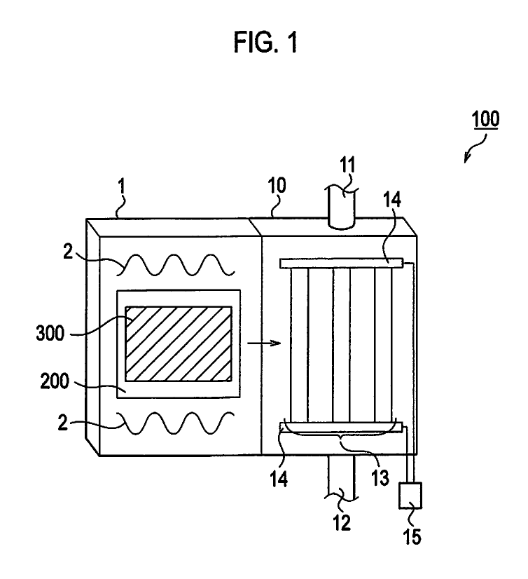

Hereinafter, a configuration of a catalytic CVD equipment according to the embodiment will be described with reference to the drawings. FIG. 1 is a schematic diagram showing a configuration of a catalytic CVD equipment 100.

As shown in FIG. 1, the catalytic CVD equipment 100 has a preparation chamber 1, a reaction chamber 10, and a takeout chamber (not shown). A substrate 300 that is held on a substrate tray 200 is moved from the preparation chamber 1 to the reaction chamber 10, making it possible to form a deposited film on the substrate 300.

It is to be noted that the preparation chamber 1, the reaction chamber 10, and the takeout chamber are evacuated at a pressure lower than about 1×10⁻⁴ Pa at a time other than when the film is formed in a normal operation state.

(1) Configuration of Preparation Chamber

The preparation chamber 1 is a vacuum chamber for housing the substrate tray 200, and is constituted to enable evacuation in a vacuumed state. The preparation chamber 1 is provided with a heating mechanism 2 such as a lamp heater or a sheath heater.

The heating mechanism 2 heats the substrate 300 that is held on the substrate tray 200. In this manner, the moisture that is adsorbed on the substrate tray 200 and the substrate 300 is eliminated.

In addition, the preparation chamber 1 is provided with a take-in device and a takeout device, although not shown. The take-in device takes the substrate tray 200 in the preparation chamber 1. The takeout device takes out the substrate tray 200 that is ready for preparation in the preparation chamber 1 to the reaction chamber 10.

(2) Configuration of Reaction Chamber

The reaction chamber 10 is a vacuum chamber for housing the substrate tray 200. The reaction chamber 10 is provided with a gas supply pipe 11, a gas discharge pipe 12, a plurality of catalytic wires 13, a mount portion 14, and a power source 15.

The gas supply pipe 11 is a flow path for supplying a raw material gas (such as a mixture gas of SiH₄ and H₂ or SiH₄, for example) into the reaction chamber 10.

The gas discharge pipe 12 is a flow path for discharging a raw material gas from the inside of the reaction chamber 10.

The catalytic wires 13 are heated to thereby decompose the raw material gas to be supplied into the reaction chamber 10. Both ends of the catalytic wires 13 are mounted to the mounted portion 14, and are disposed perpendicular to a bottom face of the reaction chamber 10. The catalytic wires 13 are heated to a temperature at which a raw material gas can be decomposed (hereinafter, referred to as a “decomposition temperature”, which is 1,600 degrees Centigrade to 2,000 degrees Centigrade, for example), by means of power supply. The raw material gas is decomposed by means of the catalytic wires 13, and decomposed species reaches the substrate 300, whereby a deposited film (such as a semiconductor film or a SiN film, for example) is formed on the substrate 300.

The catalytic wires 13 can be made of a material such as Ta, Mo, or W-based wires. In addition, the catalytic wires 13 may have different kinds of layers on surface. One example of such wires includes a tantalum wire of which a borate layer is formed on surface. Further, the catalytic wires 13 with their diameter of 0.3 mm to 2.0 mm, preferably 0.5 mm to 1.0 mm are employed.

The power source 15 supplies power to the catalytic wires 13 via the mount portion 14. As the power source 15, there can be employed a constant current/constant voltage power supply that is capable of constant current power supply, constant voltage power supply or both of constant current power supply and constant power control.

In the embodiment, control of the power supply 15 may be either one of constant current control and constant power control, and a temperature of the catalytic wires 13 is controlled by setting a current value or a power value. That is, the current value or power value of the power source 15 is controlled so that a current flows into the catalytic wires 13 to an extent such that the temperature of the catalytic wires 13 is set at a predetermined temperature.

In addition, the reaction chamber 10 is provided with a take-in device and a takeout device, although not shown. In this manner, the substrate tray 200 is taken in the reaction chamber 10 or is taken out from the reaction chamber 10.

(3) Configuration of Control Unit

The catalytic CVD equipment 100 has a control unit, although not shown.

The control unit always continuously supplies power to the catalytic wires 13 at the time of continuous operation of the catalytic CVD equipment 100.

Specifically, at time intervals at which formation of film is to be performed on the substrate 300 in the reaction chamber 10 (hereinafter, referred to as “time intervals when a film is formed”), the control unit power-supplies a current at which a temperature of the catalytic wires 13 can be heated to a decomposition temperature of a raw material gas. In addition, at time intervals at which formation of film is not performed on the substrate 300 in the reaction chamber 10 (hereinafter, referred to as “time intervals when no film is formed”), the control unit power-supplies a current at which the temperature of the catalytic wires 13 can be controlled to a temperature which is lower than the temperature of the catalytic wires 13 when the film is formed, and is higher than room temperature. In this way, power is continuously supplied to the catalytic wires 13 when the substrate tray 200 is not housed in the reaction chamber 10 as well. Therefore, the catalytic wires 13 are always powered from the time when the film is formed over the time when no film is formed.

In addition, it is preferable that a temperature of the catalytic wires 13 when no film is formed (hereinafter, referred to as a “standby temperature”) be a temperature which is lower than a temperature of the catalytic wires 13 when the film is formed, and be a temperature which is lower than a decomposition temperature of a raw material gas. In this manner, the catalytic wires 13 can be restrained from being always heated to a high temperature, thus making it possible to lessen expansion of the catalytic wires 13. As a result, extended serviceable life of the catalytic wires 13 can be realized.

Further, it is preferable that a standby temperature be a temperature which is higher than a temperature when power supply to the catalytic wires 13 has been stopped (the order of room temperature), and be a temperature which is higher than a ductile-brittle transition temperature of the catalytic wires 13.

The “ductile-brittle transition” used herein denotes a phenomenon in which, in a case where a temperature of the catalytic wires has lowered, a material constituting the catalytic wires becomes significantly vulnerable due to the lowering of the temperature. In addition, the “ductile-brittle transition temperature” used herein denotes a temperature at which an ductile-brittle transition occurs with the catalytic wires or part of these wires. For example, the ductile-brittle transition temperature of tungsten (W), which is well known as a material for the catalytic wires, is 300 degrees Centigrade, and becomes extremely vulnerable if a temperature of less than 300 degrees Centigrade is reached. Therefore, in a case where W is employed for the catalytic wires, the standby temperature is set at a temperature which is higher than 300 degrees Centigrade that is the ductile-brittle transition temperature, thereby making it possible to realize extended serviceable life of the catalytic wires.

Although an ductile-brittle transition temperature in a case where the catalytic wires 13 have a laminate structure is not clear, for example, it is experimentally verified that, in catalytic wires employing tantalum having a tantalum borate layer on surface, a standby temperature is set at a temperature exceeding 500 degrees Centigrade to thereby realize extended serviceable life. Therefore, in the case of tantalum having a tantalum borate layer on surface, it is deemed that the ductile-brittle transition temperature is about 500 degrees Centigrade.

In addition, the temperature of the catalytic wires 13 when the film is formed can be appropriately selected as long as it is a temperature at which a raw material gas can be decomposed (i.e., a decomposition temperature), or alternatively, the temperature may be varied. Similarly, the standby temperature can be appropriately selected at a temperature which is lower than the temperature of the catalytic wires 13 when the film is formed, and is higher than room temperature, or alternatively, the temperature can be varied.

[Method for Formation of Film Employing Catalytic CVD Equipment]

Next, as one example of a method for formation of film employing the catalytic CVD equipment 100, a method for forming a semiconductor film will be described with reference to the drawings.

(1) Preparation Chamber 1

First, the substrate 300 having a first main face and a second main face that is provided at an opposite side of the first main face is prepared. In the embodiment, the substrate 300 is made of a material such as glass.

Next, the substrate 300 is held on the substrate tray 200.

Next, the substrate tray 200 on which the substrate 300 is held is taken in the preparation chamber 1 that is maintained at an atmospheric pressure.

Next, by means of evacuation from a evacuation system, the inside of the preparation chamber 1 is evacuated at a predetermined pressure (1×10⁻⁴ Pa or less, for example), and by means of the heating mechanism 2, the substrate 300 and the substrate tray 200 are heated to the order of about 150 degrees Centigrade to 200 degrees Centigrade. In this manner, the moisture that is adsorbed to the substrate 300 and the substrate tray 200 is eliminated.

(2) Formation of Amorphous Si Film

Next, the substrate tray 200 on which the substrate 300 is held is taken from the preparation chamber 1, and is transferred into the reaction chamber 10. At this time, the catalytic wires 13 that are disposed in the reaction chamber 10 are preheated at a standby temperature by means of continuous power supply.

Next, a mixture gas of SiH₄ and H₂ is supplied as a raw material gas from the gas supply pipe 11 into the reaction chamber 10, and the pressure in the reaction chamber 10 is adjusted to a predetermined value (about 0.5 Pa to 10 Pa, for example).

Next, by increasing the current flowing in the catalytic wires 13, the catalytic wires 13 are heated up to a decomposition temperature of a raw material gas. In this manner, the raw material gas is decomposed by means of the catalytic wires 13, and decomposed species reaches the top of the first main face of the substrate 300. In this manner, an amorphous Si film is formed on the substrate 300.

Next, the current flowing in the catalytic wires 13 is reduced, and at the same time, supply of the raw material gas is stopped. In this manner, the catalytic wires 13 are heated up to a standby temperature by means of continuous power supply.

Next, after the pressure in the reaction chamber 10 has been set at about 1×10⁻⁴ or less by means of evacuation from the gas discharge pipe 12, the substrate tray 200 on which the substrate 300 is held is taken out to the takeout chamber and then is exposed in atmosphere.

While, in the embodiment, the current flowing in the catalytic wires 13 is reduced, and at the same time, supply of the raw material gas is stopped, the supply of the raw material gas may be stopped after the current has been reduced, or alternatively, the current may be reduced after the supply of the raw material gas has been stopped.

Next, a substrate tray 200 on which a newly prepared substrate 300 is held is taken from the preparation chamber 1 and then is transferred into the reaction chamber 10. At this time, the catalytic wires 13 are maintained at a standby temperature by means of continuous power supply.

Next, the abovementioned raw material gas is supplied from the gas supply pipe 11 into the reaction chamber 10, whereby the pressure in the reaction chamber 10 is adjusted to a predetermined value (about 0.5 Pa to 10 Pa, for example).

Next, by increasing the current flowing in the catalytic wire 13, the catalytic wires 13 are heated up to the decomposition temperature of the raw material gas. In this manner, the raw material gas is decomposed by means of the catalytic wires 13, and decomposed species reaches the top of the substrate 300.

As described above, in a case where formation of film on the substrate 300 is continuously performed, in the embodiment, the temperature of the catalytic wires 13 is controlled to a standby temperature which lower than the temperature of the catalytic wires 13 when the film is formed and is higher than room temperature before and after the film is formed on the substrate 300.

[Functions and Advantageous Effects]

In the catalytic CVD equipment 100 according to the embodiment, the control unit controls a temperature of the catalytic wires 13 to a standby temperature at predetermined time intervals before and after the film is formed. The standby time is a predetermined temperature which is lower than the temperature of the catalytic wires 13 when the film is formed, and is higher than room temperature.

Therefore, shrinkage and expansion that occur with the catalytic wires 13 can be mitigated in comparison with a case in which start and stop of power supply by means of the power source 15 is repeated. Thus, extended serviceable life of the catalytic wires 13 can be realized.

In addition, the standby temperature is lower than the temperature of the catalytic wires 13 when the film is formed. Therefore, the catalytic wires 13 are always maintained at a high temperature, whereby the catalytic wires can be restrained from being maintained in its expanded state.

Further, the catalytic wires 13 are not always set at a decomposition temperature, thus making it possible to restrain the substrate 300 from being overheated. As a result, the quality of film that is formed on the substrate 300 can be restrained from being degraded.

Furthermore, it is preferable that the standby temperature be higher than the ductile-brittle transition temperature of the catalytic wires 13. In this case, the fact that the ductile-brittle transition temperature occurs with the catalytic wires 13 can be restrained, thus making it possible to realize extended serviceable life of the catalytic wires 13.

Still furthermore, it is preferable that the standby temperature be a temperature at which a temperature of the substrate 300 can be maintained to be lower than a temperature at which film quality of a film such as an amorphous semiconductor film or a finely crystalline semiconductor film formed on the substrate 300 varies. In this case, variation of the film quality can be restrained in the case where the film such as the amorphous semiconductor film or the finely crystalline semiconductor film has been formed on the substrate 300 as well.

Yet furthermore, power is continuously supplied to the catalytic wires 13 at predetermined time intervals before and after the film is formed, whereby the catalytic wires 13 can be controlled at a predetermined temperature without a need to employ another heating mechanism such as a heater. As a result, reduction of equipment costs can be realized.

Moreover, in the method for formation of film according to the embodiment, the abovementioned catalytic CVD equipment 100 is employed, thus making it possible to lessen replacement frequency of the catalytic wires 13. As a result, manufacturability of films can be improved.

### Other Embodiments

While the present invention was described by way of the foregoing embodiment, it should not be understood that the statements and drawings forming part of this disclosure limits the present invention. From this disclosure, a variety of substitutive embodiments, examples, and operating techniques would have been self-evident to one skilled in the art.

In the foregoing embodiment, for example, while a method for forming an amorphous Si film was described as one example of the method for formation of film to which the present invention is applied, the present invention is not limitative thereto. The present invention is also applicable to a method for forming a semiconductor film other than the amorphous Si film or a film other than a semiconductor film such as a SiN film. Further, the present invention is also applicable to a method for manufacturing semiconductor devices such as solar cells which are provided with at least one of a semiconductor film and films other than the semiconductor films.

In addition, while, in the foregoing embodiment, the catalytic CVD equipment 100 was arranged to be provided with only one reaction chamber 10, the present invention is not limitative thereto. The catalytic CVD equipment 100 may be provided with a plurality of reaction chamber. In this manner, films of a same kind or different kinds can be formed to be superimposed on the substrate 300. In a case where a film is further formed on a film that is formed on the substrate 300, it is preferable that the standby temperature be a temperature at which the temperature of the substrate 300 can be maintained to be lower than a temperature at which the quality of film that is formed on the substrate 300 varies. For example, in a case where an amorphous semiconductor film or a finely crystalline semiconductor film has been formed on the substrate 300, the standby temperature is controlled to a temperature at which the temperature of the substrate 300 can be maintained at about 300 degrees Centigrade or less, thereby making it possible to restrain variation of film quality due to elimination of hydrogen or the like.

### EXAMPLE

While Example of the catalytic CVD technique according to the present invention will be specifically described, it is to be noted that the present invention is not limitative to the descriptive matters set forth in the following Example, and can be appropriately modified and carried out without departing from the spirit and scope of the invention.

### Example

First, a tantalum wire whose surface had been borated was disposed as a catalytic wire in a reaction chamber.

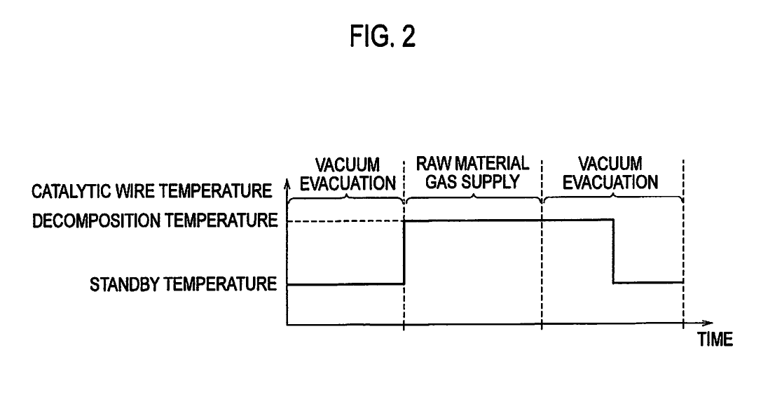

Next, heating and cooling of the catalytic wire were repeatedly performed in accordance with the flowchart shown in FIG. 2.

Specifically in the step of vacuum-evacuating the inside of the reaction chamber in advance, a temperature of the catalytic wire was first maintained at a standby temperature (500 degrees Centigrade to 700 degrees Centigrade).

Next, the temperature of the catalytic wire was maintained at a decomposition temperature (1,600 degrees Centigrade to 2,000 degrees Centigrade) from the step of supplying a raw material gas into the reaction chamber up to partway of the step of vacuum-evacuating the raw material gas from the inside of the reaction chamber.

Next, the temperature of the catalytic wire was maintained at the standby temperature by continuously supplying power to the catalytic wire from partway of the step of vacuum-evacuating the raw material gas.

Then, the above steps were repeatedly performed until the catalytic wire had broken.

### Comparative Example

In Comparative Example, no power was supplied to the catalytic wire from the step of vacuum-evacuating the inside of the reaction chamber in advance and partway of the step of vacuum-evacuating a raw material gas. Everything else was performed in the same manner as that in Example.

### Result

In Example, serviceable life of the catalytic wire could be increased to be twice or more in comparison with that in Comparative Example. A reason why such a result was obtained is that power was continuously supplied to the catalytic wire in Example, and expansion and shrinkage of the catalytic wire could be mitigated.

It is to be noted that the entire contents of Japanese Patent Application Publication No. 2009-230598 (filed in Oct. 2, 2009) are incorporated in the present specification by reference.

### INDUSTRIAL APPLICABILITY

As described above, a catalytic CVD equipment according to the present invention is useful in the field of manufacturing catalytic CVD equipments, since extended serviceable life of catalytic wires can be realized. In addition, a method for formation of film and a process for production of solar cell, according to the present invention, are useful in the field of manufacturing solar cells, since manufacturability can be improved.

### DESCRIPTION OF REFERENCE NUMERALS

1 . . . Preparation chamber
2 . . . Heating mechanism
10 . . . Reaction chamber
11 . . . Gas supply pipe
12 . . . Gas discharge pipe
13 . . . Catalytic wire
14 . . . Mount portion
15 . . . Power source
100 . . . Catalytic CVD equipment
200 . . . Substrate tray
300 . . . Substrate

1. A catalytic CVD equipment for performing formation of film by supplying a raw material gas to a catalytic wire that is installed and heated in a reaction chamber and then depositing generated decomposed species on a film-formed substrate in the reaction chamber,
the equipment comprising a control unit that is capable of controlling a temperature of the catalytic wire so as to reach a decomposition temperature of the raw material gas, at a time of formation of film onto the film-formed substrate,
the control unit being capable of controlling the temperature of the catalytic wire so as to be a predetermined temperature which is lower than the temperature of the catalytic wire when the film is formed, and is higher than room temperature, at each of predetermined time intervals before and after the film is formed.

2. A catalytic CVD equipment for performing formation of film by supplying a raw material gas to a catalytic wire that is installed and heated in a reaction chamber and then depositing generated decomposed species on a film-formed substrate in the reaction chamber,
the equipment comprising a power source for supplying power to the catalytic wire,
the device comprising a control unit controlling power supply to the catalytic wire so that the temperature of the catalytic wire is set at a decomposition temperature of the raw material gas at the time of formation of film onto the film-formed substrate,
the control unit controlling power supply to the catalytic wire so that the temperature of the catalytic wire is set at a predetermined temperature which is lower than the temperature of the catalytic wire when the film is formed, and is higher than room temperature at each of the predetermined time intervals before and after the film is formed.

3. The catalytic CVD equipment according to claim 1, wherein the catalytic wire is temperature-controlled by means of continuous power supply at each of the predetermined time intervals before and after the film is formed.

4. The catalytic CVD equipment according to claim 1, wherein a temperature of the catalytic wire is controlled to reach a temperature which is lower than the decomposition temperature at each of the predetermined time intervals before and after the film is formed.

5. The catalytic CVD equipment according to claim 1, wherein the predetermined temperature is a temperature which is higher than a temperature at which an ductile-brittle transition occurs with at least part of the catalytic wire.

6. The catalytic CVD equipment according to claim 1, wherein the predetermined temperature is a temperature at which, in a case where a predetermined film has been formed on the film-formed substrate, a temperature of the film-formed substrate is maintainable to be lower than the temperature at which the film quality of the predetermined Mm varies.

7. A method for formation of film including the step of forming a film on a film-formed substrate by employing the catalytic CVD equipment according to claim 1.

8. A process for production of solar cell including the step of forming a film on a film-formed substrate by employing the catalytic CVD equipment according to claim 1.

9. The catalytic CVD equipment according to claim 2, wherein the catalytic wire is temperature-controlled by means of continuous power supply at each of the predetermined time intervals before and after the film is formed.

10. The catalytic CVD equipment according to claim 2, wherein a temperature of the catalytic wire is controlled to reach a temperature which is lower than the decomposition temperature at each of the predetermined time intervals before and after the film is formed.

11. The catalytic CVD equipment according to claim 2, wherein the predetermined temperature is a temperature which is higher than a temperature at which an ductile-brittle transition occurs with at least part of the catalytic wire.

12. The catalytic CVD equipment according to claim 2, wherein the predetermined temperature is a temperature at which, in a case where a predetermined film has been formed on the film-formed substrate, a temperature of the film-formed substrate is maintainable to be lower than the temperature at which the film quality of the predetermined film varies.

13. A method for formation of film including the step of forming a film on a film-formed substrate by employing the catalytic CVD equipment according to claim 2.

14. A process for production of solar cell including the step of forming a film on a film-formed substrate by employing the catalytic CVD equipment according to claim 2.
